(19) United States
(12) Patent Application Publication
(10) Pub. No.: US 2008/0024327 A1
(43) Pub. Date: Jan. 31, 2008

(54) METHOD AND APPARATUS FOR ERGONOMIC KEYBOARD

(76) Inventors: Trevor A. Downs, Temecula, CA (US); Shafer Ray Taylor, Farmington, UT (US); Russell Gary Stout, Riverton, UT (US); Jeffrey Robert Jackson, Little Rock, AR (US); Jason A. Jackson, Mapleton, UT (US); James Richard Cook, Malaga, WA (US)

Correspondence Address: MARC E. HANKIN, ESQ., 11414 THURSTON CIRCLE, LOS ANGELES, CA, 90049, US

(21) Appl. No.: 11/695,600

(22) Filed: Apr. 2, 2007

Related U.S. Application Data
(63) Continuation-in-part of application No. 29/257,471, filed on Apr. 3, 2006, now Pat. No. D540335.
(60) Provisional application No. 60/833,463, filed on Jul. 25, 2006.

(51) Int. Cl. H03K 17/94; H03M 11/00

(52) U.S. Cl. 341/22; 400/489

(57) ABSTRACT

Keys of a keypad are configured to exhibit a wave-like vertical profile across a width of the keypad, thereby improving user comfort. Keys on the edge of the main grouping are raised, with the height of adjacent keys gradually reduced until a minimum (trough) is achieved. The height of the further adjacent keys is then increased until a maximum (peak) is achieved. In accordance with one embodiment, the keyboard includes two key troughs separated by an intervening raised key portion. The key troughs are positioned at the approximate location of hands resting on the home row of keys, for example in the case of a QWERTY keypad at the “D” key and at the “K” or “L” keys. The continuous, flowing change in the vertical profile of the keycaps renders the keyboard more accessible to the natural, relaxed state of the human hand, easing physical strain.

### RELATED APPLICATIONS

This application is a Continuation-In-Part of U.S. application Ser. No. 29/257,471, filed on Apr. 3, 2006, and claims priority to the U.S. Provisional Patent Application No. 60/833,463, filed on Jul. 25, 2006. Both application Ser. Nos. 29/257,471 and 60/833,463 are incorporated herein by reference.

### BACKGROUND OF THE INVENTION

Computing technologies have proliferated over the years. In the early days, large mainframe computers dominated the computing landscape. These large mainframe computers were developed by companies such as IBM Corporation of Armonk, N.Y. Mainframe computers have been replaced, at least in part, by smaller personal computing devices, commonly known as “PCs.” PCs come in various shapes and sizes. PCs are often run using computer software such as Windows from Microsoft Corporation from Redmond Wash. Other types of computer software come from Apple Computer of Cupertino, Calif. Smaller PC versions are often called “lap top computers.” Other types of PCs include larger desktop versions. Still other versions of PCs can be found in smaller devices such as personal digital assistants, called PDAs, cellular phones, and a variety of other applications.

More and more people are spending larger portions of their day working on a computer. Common to most computing devices is a keyboard for entry of data. Many different arrangements of keycaps on keypads exist. One of the most common keyboard layouts is known as the “QWERTY” keyboard, because the first six keys on the top row of letters spell QWERTY. Other types of keyboard arrangements include the Dvorak keyboard, and keyboards for non-Roman alphabetic scripts.

Keyboards are the way most people interface with a computer, and typing is an important part of many daily lives. However, increased computer usage has created physical problems which many computer users experience on a daily basis. Specifically, conventional keyboard designs typically arrange the keys in a flat or slightly elevated manner. However, in a relaxed state the human hand is not configured to easily move the fingers to manipulate such an arrangement of keys. Accordingly, tendons or muscles of the users of conventional keyboard designs may experience fatigue or soreness in the fingers, hands, wrists, and/or arms, and in extreme cases may develop one of the family of conditions known as Cumulative Stress Disorders (CTD's), which include Carpal Tunnel Syndrome, Tendonitis, and other ailments.

Specifically, the repetitive motion of typing over a long period of time can create a strain that results in a damaging effect upon the hand and finger joints and the associated respective muscles, tendons, and ligaments. This can cause discomfort and may require surgery to repair. Repetitive stress injuries (RSI) accounted for one in four lost-time injuries and illnesses reported by employers to the Bureau of Labor Statistics—615,000 in 1993. In all, insurers awarded an estimated 2.73 million workers' compensation claims for RSIs in 1993, costing employers more than $20 billion. Indirect costs to employers are estimated to be five times that amount—$100 billion. It is apparent from these statistics that consumers need keyboards that are comfortable and ergonomically designed to reduce the damaging effects of typing.

A number of studies have focused upon the effect of keyboard design on physical strain to users. Incorporated by reference herein for all purposes are each of the following references: Lueder and Grant, “Alternative keyboard designs. An ergonomics review of the literature for the National Institute of Occupational Safety and Health Ergonomics Review”, Humanics, p. 28 (1997); Hedge et al., “Effects of keyboard tray geometry on upper body posture and comfort”, Ergonomics, Vol. 42, pp. 1333-1349 (1999); Pargh, “Computer comparisons”, Design News, Vol. 50, p. 216 (1994); Serina et al., “Wrist and forearm postures and motions during typing”, Ergonomics, Vol. 42, pp. 938-951 (1999); Simoneau et al., “Effect of Computer Keyboard Slope on Wrist Position and Forearm Electromyography of Typists Without Musculoskeletal Disorders”, Physical Therapy, Vol. 83, No. 9 (2003); and Fagarasanu et al., “The training effect on typing on two alternative keyboards”, International Journal of Industrial Ergonomics, Vol. 35, pp. 509-516 (2005).

Keyboard manufacturers have begun marketing keyboards that reduce the strain associated with typing. Many such keyboards manufactured for ergonomic benefit exhibit key shapes and/or key layouts quite different from the traditional devices users are accustomed to seeing. Keyboards exhibiting such variation from the traditional design have created niche markets of users who value the unique features of each ergonomic design. Although ergonomic features have been added to keyboards without creating a niche market, no known keyboard designs have been made that are truly ergonomic while maintaining the traditional appearance.

From the above, it is seen that a need exists in the art for improved apparatuses and methods for utilizing a keyboard acceptable to a broad market demographic, while incorporating ergonomic features that reduce typing strain.

### BRIEF SUMMARY OF THE INVENTION

In accordance with embodiments of the present invention, keys of a keypad are configured to exhibit a wave-like vertical profile across a width of the keypad, thereby improving user comfort. Keys on the edge of the main grouping are raised, with the height of adjacent keys gradually reduced until a minimum (trough) is achieved. The height of the further adjacent keys is then increased until a maximum (peak) is achieved. In accordance with one embodiment, the keyboard includes two key troughs separated by an intervening raised key portion. The key troughs are positioned at the approximate location of hands resting on the home row of keys, for example in the case of a QWERTY keypad at the “D” key and at the “K” or “L” keys. The continuous, flowing change in the vertical profile of the keycaps renders the keyboard more accessible to the natural, relaxed state of the human hand, easing physical strain.

An embodiment of a keyboard in accordance with the present invention comprises keys exhibiting a wave-like vertical profile along a width axis, a first set of keys at edges of the keyboard elevated relative to a second set of keys located in troughs at an expected location of rest of hands of a user on a home key row, the second set of keys separated by a third, elevated middle set of keys.

An embodiment of a method in accordance with the present invention for designing a keyboard, comprises, generating a wave-like curve along a width axis, and fabricating a plurality of keycaps having top surfaces conforming to the wave-like curve.

An embodiment of a method in accordance with the present invention for easing physical strain associated with typing, comprises, providing a keyboard having keycaps exhibiting a wave-like vertical profile along a width axis.

An embodiment of a QWERTY keypad in accordance with the present invention, comprises, keys whose top surfaces exhibit a continuous wave-like vertical profile conforming to a continuous smooth wave form along a width axis, a first set of keys at edges of the keypad elevated relative to a second set of keys located in troughs at “D” and “K” keys of the home key row, the second set of keys separated by a third, elevated middle set of keys, wherein a difference between a highest key and a lowest key is not greater than 5 mm and the vertical profile of the keys increases along a depth axis from a first row including a space bar keycap to a second row including a number keycap.

An embodiment of a method in accordance with the present invention of designing a keyboard, comprises, utilizing a computer to generate a continuous smooth waveform along a horizontal axis, and fabricating a QWERTY keypad having keys whose top surfaces conform to the computer-generated waveform, a first set of keys at edges of the keypad elevated relative to a second set of keys located in troughs at “D” and “K” keys of a home key row, the second set of keys separated by a third, elevated middle set of keys, wherein a difference between a highest key and a lowest key is not greater than 5 mm and the vertical profile of the keys increases along a depth axis from a bottom row including a space bar keycap to a top row including a number keycap.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1A is a simplified plan view of an embodiment of a keyboard device in accordance with the present invention.

FIG. 1B is a simplified end-view diagram showing the keyboard embodiment of FIG. 1A.

FIG. 2 is a simplified perspective view of an alternative embodiment of a keyboard device in accordance with the present invention.

FIG. 2A is a simplified elevational side view of the top surface of the keys of the main portion of the embodiment of the keyboard embodiment of FIG. 2.

FIG. 3A is a simplified plan view of a row of keys of an embodiment in accordance with the present invention, exhibiting the wave-like profile.

FIG. 3B is a simplified cross-sectional view of the row of keys shown in FIG. 3A.

FIG. 3C is a simplified perspective view of the row of keys shown in FIG. 3A.

FIG. 4 is a simplified perspective view of a keyboard in accordance with an alternative embodiment of the present invention.

FIGS. 4A-E show simplified cross-sectional views of the various rows of keys of the keyboard embodiment of FIG. 4.

FIG. 5 is a simplified perspective view of a keyboard in accordance with an alternative embodiment of the present invention.

FIGS. 5A-E show simplified cross-sectional views of the various rows of keys of the keyboard embodiment of FIG. 5.

FIG. 6 is a simplified back-side diagram of a keyboard device according to an embodiment of the present invention.

FIG. 7 is a simplified block diagram of a keyboard system according to an embodiment of the present invention.

FIG. 8 shows a simplified chart illustrating methods of designing a keyboard in accordance with an embodiment of the present invention.

### DETAILED DESCRIPTION OF THE INVENTION

In accordance with embodiments of the present invention, keys of a keypad are configured to exhibit a wave-like vertical profile across a width of the keypad, thereby improving user comfort. Keys on the edge of the main grouping are raised, with the height of adjacent keys gradually reduced until a minimum (trough) is achieved. The height of the further adjacent keys is then increased until a maximum (peak) is achieved. In accordance with one embodiment, the keyboard includes two key troughs separated by an intervening raised key portion. The key troughs are positioned at the approximate location of hands resting on the home row of keys, for example in the case of a QWERTY keypad at the “D” key and at the “K” or “L” keys. The continuous, flowing change in the vertical profile of the keycaps renders the keyboard more accessible to the natural, relaxed state of the human hand, easing physical strain.

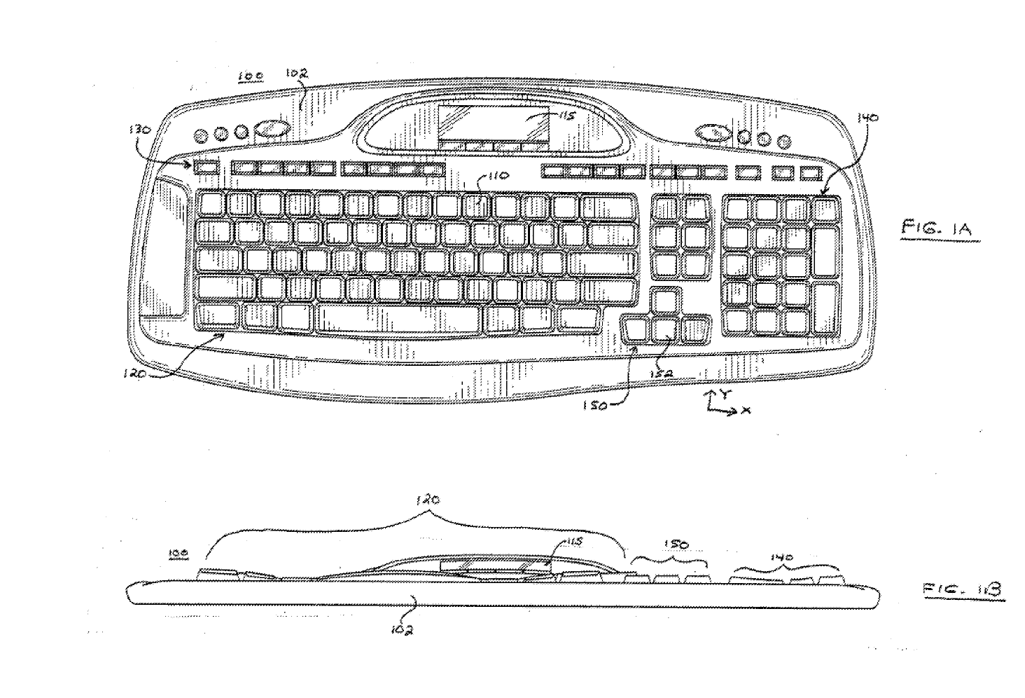

FIG. 1A is a simplified plan view of a keyboard device 100 according to an embodiment of the present invention. This diagram is merely an example, which should not unduly limit the scope of the claims herein. One of ordinary skill in the art would recognize other variations, modifications, and alternatives.

As shown, the keyboard device 100 includes a housing member 102. In specific embodiments, the housing member is often made of a suitable plastic material and/or metal that has support and can protect the internal devices in the keyboard.

Housing 102 includes a plurality of keys 110 arranged in rows along a width axis X, and staggered columns along a depth axis Y. Keys 110 are organized into a plurality of different regions. For example, main portion 120 includes alphanumeric keys (e.g., letters and numbers), and punctuation keys (e.g., comma, period, semicolon, question mark). A second region 130 of keys includes a row of function keys (e.g. F1-F12) as are often used. A third region 140 of keys includes a numerical keypad. A fourth region 150 of keys includes miscellaneous keys such as arrow keys 152. Other types of keys can be Page Up, Page Down, Home, End, Insert, Pause, Num Lock, Scroll Lock, Break, Caps Lock, Print Screen as featured in an IBM style keyboard design.

Keys 110 of keyboard 100 are configured to exhibit a wave-like shape. That is, keys 110 exhibit varying heights depending upon their location with a particular key grouping (i.e. main portion 120). Specifically, the wave shape of the embodiments of FIGS. 1A and 1B features two lower regions (troughs) in the main portion of the keyboard where the left and right hands of a user would be expected to rest when placed on the home row keys.

Specifically, in the embodiment of FIGS. 1A and 1B, the wave shape is highest at the edge of the keyboard (i.e. where the Enter, Caps Lock, and Shift keys are located) and dips to its lowest point in the “D” and “L” columns. This arrangement of key heights renders the wave-like shape symmetrical, creating a smooth rolling appearance of the keys across the board that is pleasing to the eye.

In the particular embodiment shown in FIGS. 1A and 1B, the shortest keys for the right hand are present in the “L” key column rather than the “K” key column. This is so despite the fact that the longest finger on the right hand rests on the “K” key. Accordingly, this particular embodiment may sacrifice some comfort of the longest finger on the right hand, in exchange for a smooth symmetrical wave appearance.

Keycaps in accordance with the embodiment of FIGS. 1A and 1B exhibit a difference in height of between about 4-5 mm from the highest keys to the lowest key along a horizontal axis, surface to surface. In accordance with other embodiments, the height difference in keys may be between 3-6 mm. An additional trough in key height is also shown as being present in the numerical keypad portion.

In the particular embodiment illustrated in FIGS. 1A and 1B, keys in the main portion 120 are arranged in the standard layout commonly known as a “QWERTY”, because the first six keys on the top row of letters spell QWERTY. Of course, alternative arrangements of keys exist in configurations such as the Dvorak keyboard.

The specific embodiment of the keyboard shown in FIG. 1A also includes certain other elements. Examples of power consuming elements include light emitting diodes (LEDs). Other power consuming elements include displays, back lighting for display devices, and other specialized input devices such as those for Smart Cards, PCMCIA type, one or more liquid crystal displays, back lighting for display devices, backlight of key caps, e.g., blue, red, white, green, and amber LEDs coupled to each key, any combination of these, and the like. Of course, there can be other variations, modifications, and alternatives.

The keyboard embodiment of FIG. 1A includes a display 115. Depending upon the embodiments, the display 115 can be a matrix or a color LCD display, or other kinds of display. In an embodiment, the display device is capable of displaying a maximum of 32 characters, which is the maximum number of characters for a valid password in some computing systems.

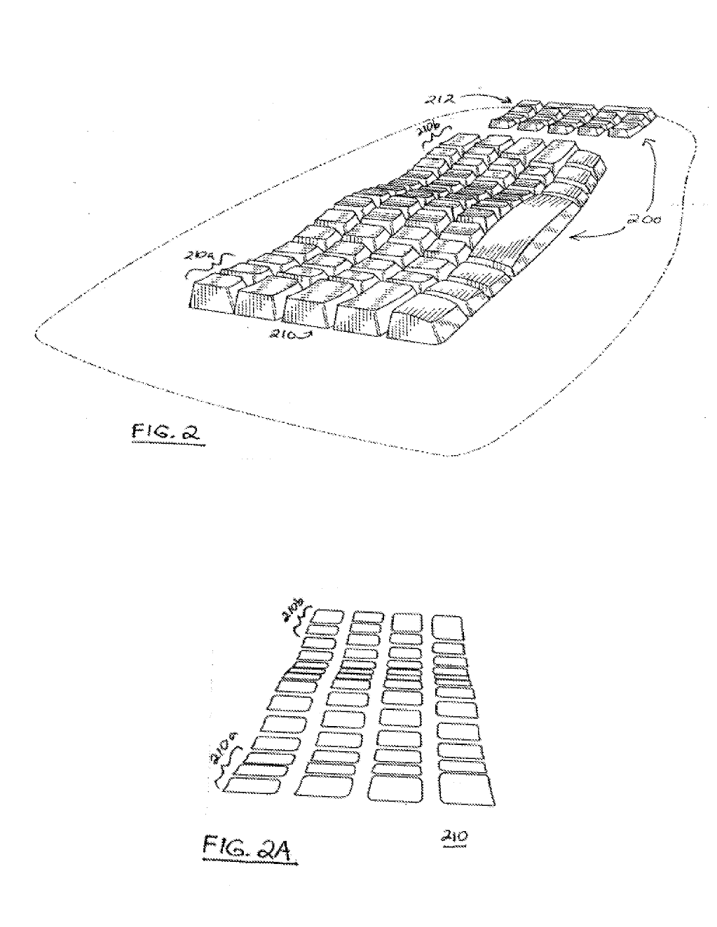

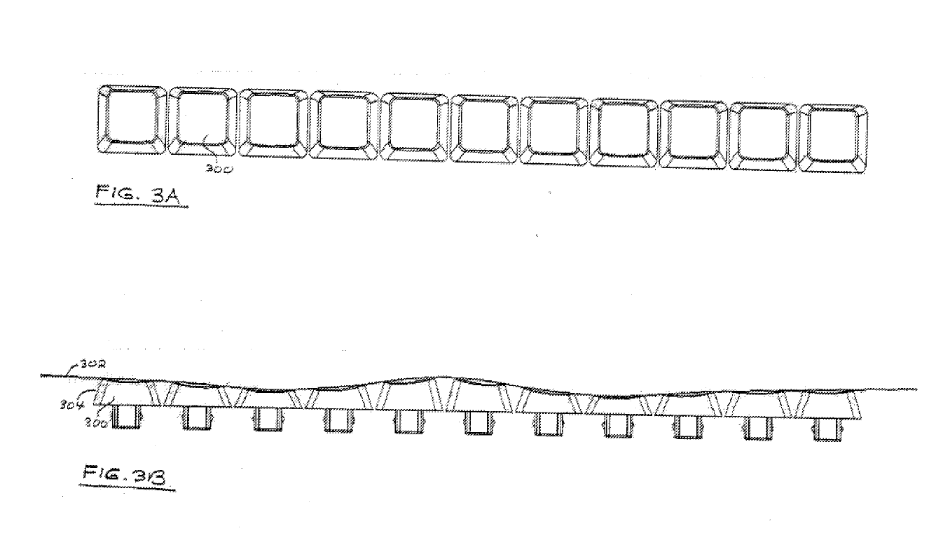

FIG. 2 is a simplified perspective view of the arrangement of keys in an alternative embodiment of a keyboard device in accordance with the present invention. FIG. 2A is a simplified elevational side view of the top surface of the keys of the main portion of the embodiment of the keyboard embodiment of FIG. 2.

Keys 200 are arranged in two groups: main portion 210 and numerical keypad 212. Keys of main portion 210 and numerical keypad 212 are designed to exhibit a wave profile. That is, the keyboard exhibits an overall ergonomic shape facilitating manipulation by a user.

For example, as shown in the embodiment of FIGS. 2-2A, the height and slope of the top surface of the keycaps varies such that the edges of the keys are aligned with a smoothly curved (“waved”) surface. This waved surface is high on left edge 210a of main portion 210, slopes down until it reaches the “D” key, then slopes up to the middle (between the “G” and “H” keys), slopes back down until it reaches the “K” key, and then slopes back up until the right edge 210b of the main portion 210 of the keys. The keycaps of the numerical keypad portion 212 also exhibit the wave profile, with key portions on the edges of grouping 212 raised relative to center portions of the grouping. The continuously varying, undulating height of the key groups is characteristic of the wave keypad in accordance with embodiments of the present invention.

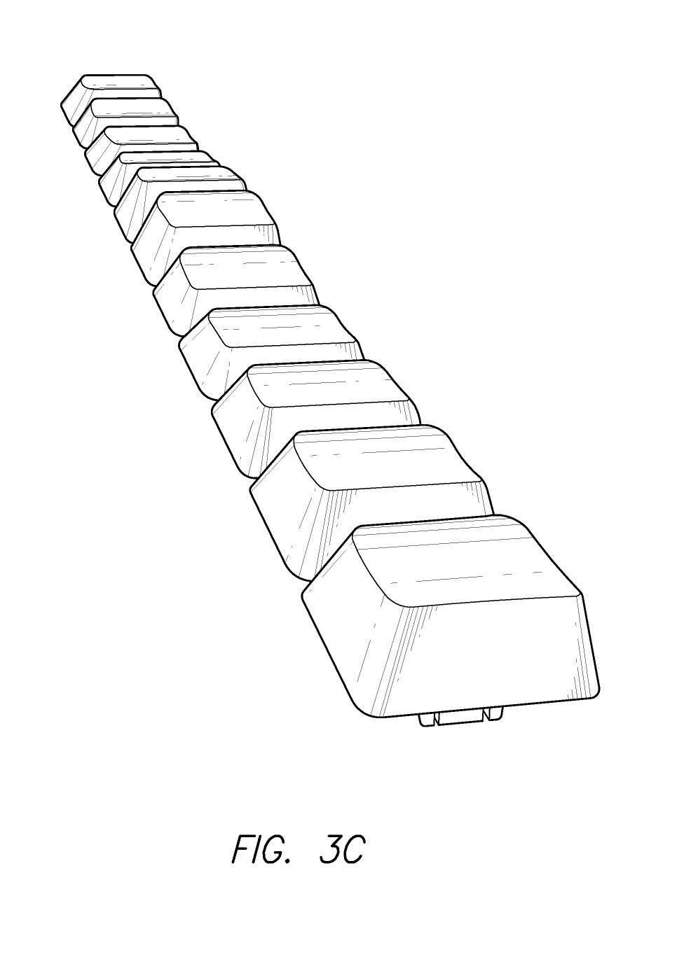

FIG. 3A is a simplified plan view of a row of keys of an embodiment in accordance with the present invention, exhibiting the wave-like profile. FIG. 3B is a simplified cross-sectional view of the row of keys shown in FIG. 3A. FIG. 3C is a simplified perspective view of the row of keys shown in FIG. 3A.

FIGS. 3A-C show that the shapes of the keys are designed to facilitate user interaction with adjacent keys. For example, as shown in FIG. 3B, the top surfaces of the adjacent keycaps 300 are angled to conform to a curve 302, so that they flow smoothly from one to the next. Because of this regular incline in the top surfaces of the keys, the fluidity of movement of fingers from one key to another is not impaired, and the user can work more quickly and in greater comfort.

The curve defining the wave-like profile to which the top surfaces of the keys conform may be created in a number of ways. In accordance with one embodiment, the curve may be generated from a mathematical equation. In accordance with an alternative embodiment, the curve may be generated by fitting of a plurality of points, for example points defining the nadir and apex of key troughs and peaks, respectively. In accordance with particular embodiments, such curve fitting may be accomplished using various Computer Aided Design (CAD) computer software programs.

A method for creating a keyboard according to an embodiment of the present invention is shown in FIG. 8. In first step 802 of process flow 800, a series of points corresponding to the expected location of top surfaces of particular keycaps are defined. In second step 804, a curve fitting the points is generated utilizing a CAD program. In third step 806, a plurality of keycaps are fabricated having top surfaces conforming to the curve. Other alternatives can also be provided where steps are added, one or more steps are removed, or one or more steps are provided in a different sequence without departing from the scope of the claims herein. Further details of the present method can be found throughout the present specification and more particularly below.

As evident from the plan view of FIG. 3A, the height of the keys does not alter the overall area occupied by them on the keypad. Specifically, in the cross-sectional view of FIG. 3B, the angle of the keycap skirt 304 changes to accommodate differences in height from one key to the next. In accordance with certain embodiments, the angle of inclination of the skirt may be varied such that taller and shorter keys will offer substantially the same surface area to the fingertips of the user. The angle of the skirt may also be dictated by manufacturing demands. For example, formation of keys by injection molding may preclude the skirt angle from being exactly perpendicular to the keycap top surface.

The length of the key skirt may change from one key to the next, so that the bottoms of the skirts are evenly aligned with each other. However, the bottom perimeter of these key skirts may be the same for each key, for example in the row of letter keys shown in FIGS. 3A-C. Thus only the shape of the keycap is changed, and positions of the keycaps need not change relative to those of a standard planar keyboard. This may be advantageous for cost purposes, facilitating manufacture of the keyboard. Specifically, during manufacture, parts of the keyboard may be injected molded with the same plastic used for conventional-type keyboards. An entire set of keys may be injected into a single mold created by machining a negative space of a computer modeled set of keys. Once the plastic hardens, the keys are separated by a machine, and letters are printed onto the top surface. The parts are then assembled by machine. Because the wave keycaps are designed to fit the conventional keyboard membrane, enclosure, and key chimneys, the same process used for manufacturing and assembling conventional keyboards can also be used to fabricate construction of the wave keyboard. This will allow the keyboard to be manufactured with a minimum cost and set-up time.

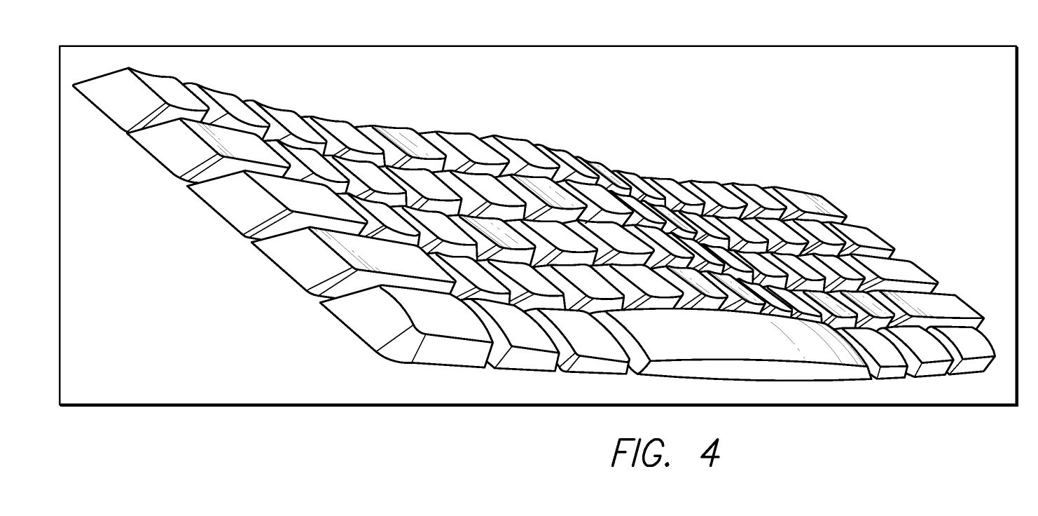

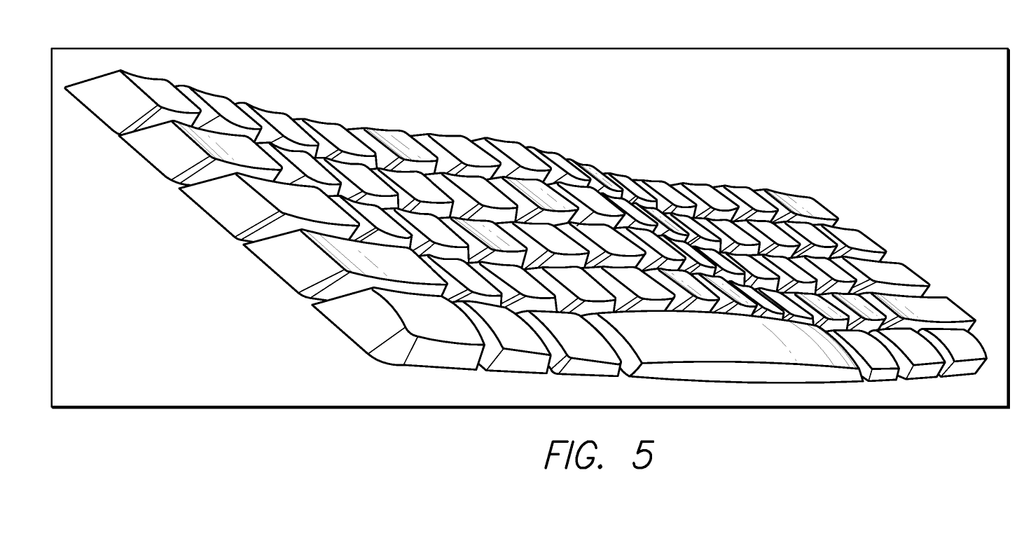

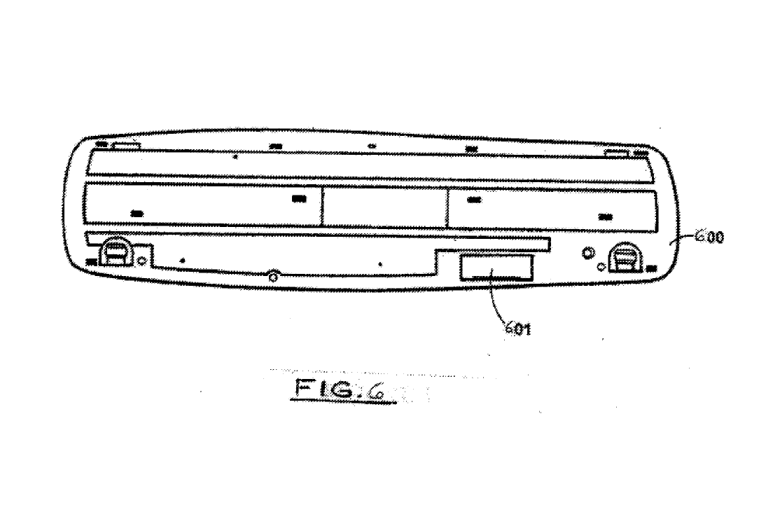

Embodiments of keyboards in accordance with the present invention may exhibit one or more features enhancing comfort of use, efficiency, or speed. For example, the shapes of the keycaps may be adjusted so that their top surfaces are more readily manipulated by the fingers. This is depicted in FIGS. 4-4E and 5-5E, which show a perspective view of the keyboard and cross-sectional views of different rows of keys, for two different embodiments of keyboards in accordance with the present invention.

In the alternative embodiment depicted in FIGS. 4-4E, letter and number keys may exhibit a concave shape so as to fit more comfortably with the rounded tip of the finger. However, the top surface of certain other keys such as the space bar and shift and enter keys located on the edge of the key grouping, are configured to exhibit a convex shape. On the row including the space bar, the top and back edge of the key conforms to a waved surface of the keyboard, but the slope of the top surface curves downward from back to front. In this particular embodiment, the difference in height between the tallest and shortest keycaps is about 4 mm. Troughs in key height occur in the columns containing the “D” and “K” keys.

The keyboard of the alternative embodiment depicted in FIGS. 5-5E exhibits a less pronounced wave profile. In particular, keys on the outer edge of the key grouping have a shallower slope, and the height difference between the tallest and shortest keycaps is about 3 mm. Troughs in key height again occur in the columns containing the “D” and “K” keys.

While the above description has focused upon an English language keyboard utilizing a standard QWERTY layout, embodiments in accordance with the present invention are not limited to this, or any other type, of key arrangement. One of skill in the art would recognize that embodiments in accordance with the present invention could be used for other keyboard arrangements, including but not limited to non-Roman alphabetic scripts.

And while the above description has provided examples wherein the vertical key profile varies along only a width axis of the keypad such that the keyboard exhibits a zero-degree tilt along a depth axis of the keyboard, the present invention is not limited to this particular configuration. In accordance with alternative embodiments, key heights may also vary along a depth axis of the keypad. Such alternative embodiments of keyboards may exhibit either a positive or negative tilt according to the particular embodiment.

Furthermore, while the above description has focused upon a keyboard for use as an input to a desktop or laptop computer, embodiments in accordance with the present invention are not limited to this particular application, and it would be recognized that the invention has a much broader range of applicability. For example, the invention can be applied to any other keypad, such as for a typewriter, word processor, video game, personal digital assistant, or TV/Entertainment system, or any combination of these, and the like. Depending upon the embodiment, the invention can be applied to provide input to any of the above devices, among others.

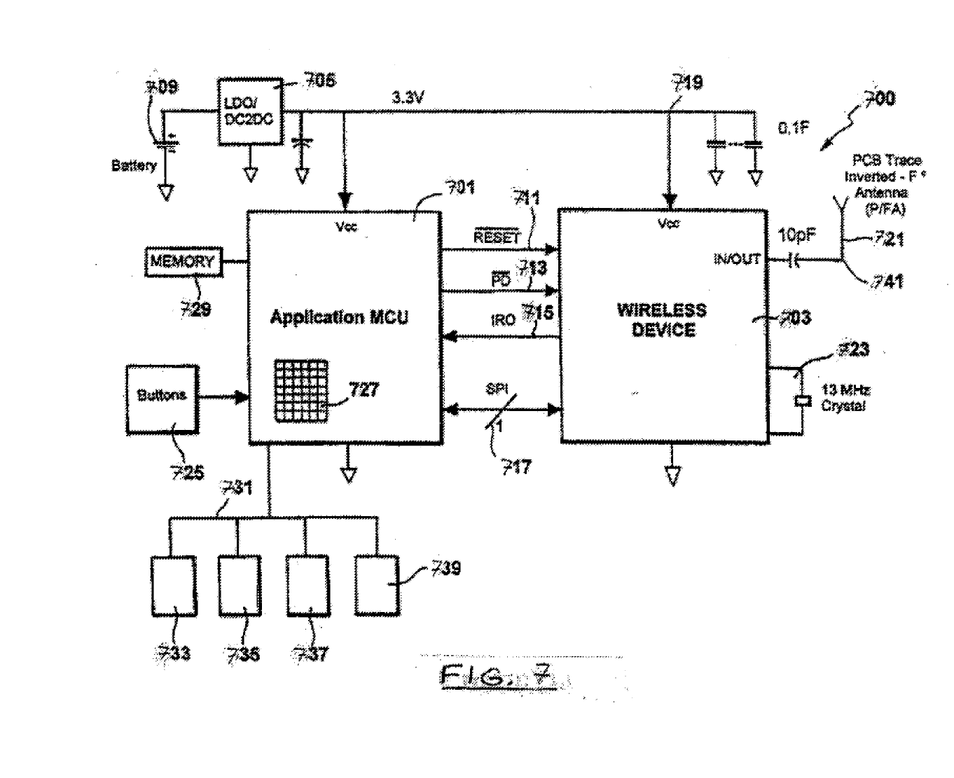

FIG. 6 is a simplified back-side diagram 600 of a keyboard device according to an embodiment of the present invention. This diagram is merely an example, which should not unduly limit the scope of the claims herein. One of ordinary skill in the art would recognize other variations, modifications, and alternatives. As shown, the backside includes an area for inserting a battery 601, which may be a single and/or multiple power sources according to a specific embodiment. Details of specific functional elements within the keyboard are provided throughout the present specification and more particularly below.

In a specific embodiment, a keyboard in accordance with the present invention may have one or more wireless devices. These wireless devices allow the keyboard and its functionality to interface with personal computers, laptop computers, television sets, and other computing based units. To provide power for these wireless devices, the keyboard has an independent battery power source. In a specific embodiment, the power source can be two or more AA batteries and/or other like type of power sources. In an embodiment, the keyboard may also have a wireless power savings process. Of course, there can be other variations, modifications, and alternatives. Further details of the keyboard can be found throughout the present specification and more particularly below.

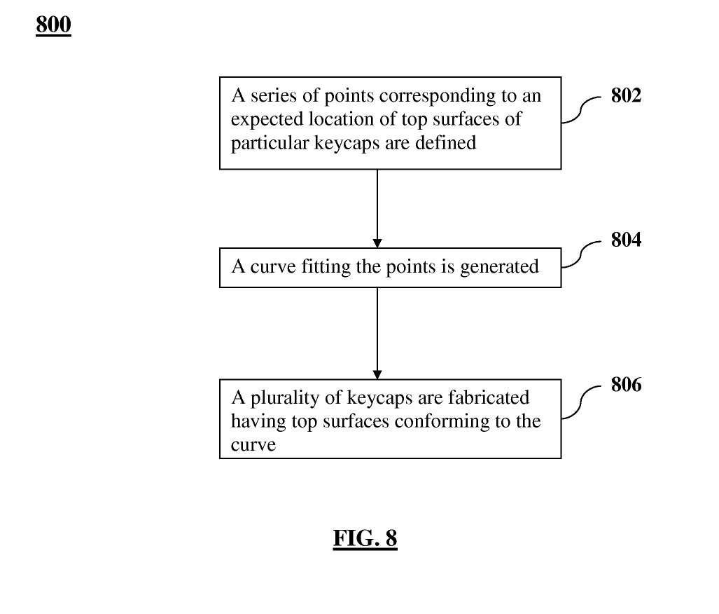

FIG. 7 is a simplified block diagram of a keyboard system 700 according to an embodiment of the present invention. This diagram is merely an example, which should not unduly limit the scope of the claims herein. One of ordinary skill in the art would recognize other variations, modifications, and alternatives. As shown, the system 700 includes various elements. These elements include a micro controller unit 701, commonly termed MCU, coupled to a wireless unit 703. The MCU is general purpose and suitable for use in the keyboard. The MCU often has a clock speed of 1 Mega Hertz and greater and also has memory, which may be embedded 727 and/or external 729 memory, to the MCU according to a specific embodiment. As merely an example, the MCU can be an Encore Series from Cypress Semiconductor Corporation of California, but can be others. Other types of MCU can be from Zilog Corporation, Intel Corporation, and other companies. Of course, there can be other variations, modifications, and alternatives.

In a specific embodiment, the memory can be any suitable memory for holding various computer codes and databases for operating at least the present methods. These memories can be volatile, such as dynamic random access memory, static random access memory, and/or Flash memory, e.g., NAND Flash. Preferably, the memory does not require a high amount of power consumption. Of course, there can be various alternatives, modifications, and variations.

As shown, the MCU couples to each of the keyboard buttons 725. The MCU often generates one or more keyboard output signals corresponding to respective one or more depression (or movements) from each key on the keyboard. The MCU transmits via SPI interface 717 the output signals to the wireless device, which outputs corresponding wireless telecommunication signals via antenna 721. Other interfaces between the wireless device and MCU include a RESET 711, IPD (Power Down) 713, IRQ (Interrupt) 715, and there also may be other elements, depending upon the specific embodiment.

In a specific embodiment, the wireless unit 703 transmits/receives wireless signals. As noted, keyboard signals converted by the MCU are transmitted via the wireless device and antenna to the computing device, such as PCs, laptop computers, work stations, and other applications. The wireless unit also includes power Vcc 719 from a power source 709. The wireless unit is also coupled to an oscillator and/or crystal 723, which provides a 13 Mega Hertz signal in a specific embodiment.

In a preferred embodiment, the wireless unit also includes a receive antenna 741, which may be the same as the transmit antenna. In a preferred embodiment, the receive antenna “sniffs” the spatial region for one or more packets from a tag device. Depending upon the embodiment, the wireless unit can use one or more wireless formats such as Blue Tooth format, IEEE 802.11 Series, and others. Depending upon the specific embodiment, the wireless unit can also be characterized by a carrier frequency of 2.4 GHz and greater, 13.0 Mega Hertz and greater, and others. The wireless unit can use various technologies such as RF sensing, infra-red sensing, and others. Of course, one of ordinary skill in the art would recognize various alternatives, modifications, and variations.

As also noted, the system has power source 709, which supplies power to the MCU, wireless unit, and other elements. That is, the power source is for supplying a direct current to the MCU and the wireless unit. The power source is generally formed at a suitable position in a bottom portion of the keyboard housing in such a way that it can be removed from the back of the bottom housing. As merely an example, the power source can be a carbon based battery or lithium based batteries, depending upon the embodiment. In a specific embodiment using the power source, the computer keyboard is stand alone and is free of an AC adapter. The power source is coupled to a voltage regulator 705, which couples to ground and has a capacitor coupled between the voltage regulator output and MCU and wireless unit according to a specific embodiment. Of course, there can be other variations, modifications, and alternatives.

In a preferred embodiment, the system also includes various power consuming devices 733, 735, 737, 739, among others. These elements receive signals from the MCU and are powered by the power source 709. The elements include a display (e.g., LCD, CMOS) 733, smart card reader 735, light emitting diodes 737, and others 739. In a specific embodiment, one or more power consuming elements uses about 50 milli-Amps having a voltage at about 3.3 volts and less. In an alternative specific embodiment, one or more power consuming elements uses about 50 milli-Amps at a voltage of about 3.3 volts and less. In a preferred embodiment, the keyboard including the one or more power consuming devices is operable at normal consumption for six months or more with a conventional power source, e.g., two AA batteries.

To turn on and turn off the MCU and related circuitry and elements using the present method and system, a wireless tag device is brought within a certain vicinity of the keyboard. Depending upon the specific embodiment, the wireless tag device can be almost any type of device capable of sending out one or more packets and/or other signals to turn on and/or turn off the MCU and related circuitry and elements. As merely an example, the wireless tag can be a personal digital assistant (PDA), cellular phone, gaming device, machine console, printer, card, automobile key, pen, any combination of these, and others. In a preferred embodiment, the wireless tag device is provided by a human user of the wireless tag device. Of course, there can be other variations, modifications, and alternatives.

In a preferred embodiment, display device 733 can be a matrix or a color LCD display, or other kinds of display device. In an embodiment, display device is capable of displaying a maximum of 32 characters, which is the maximum number of characters for a valid password in some computing systems. Of course, there can be other variations, modifications, and alternatives.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A keyboard comprising keys exhibiting a wave-like vertical profile along a width axis, a first set of keys at edges of the keyboard elevated relative to a second set of keys located in troughs at an expected location of rest of hands of a user on a home key row, the second set of keys separated by a third, elevated middle set of keys.

2. The keyboard of claim 1 wherein the troughs are located at the “D” and “K” keys of the home key row.

3. The keyboard of claim 1 wherein the troughs are located at the “D” and “L” keys of the home key row.

4. The keyboard of claim 1 wherein a difference between a highest key and a lowest key is about 3-5 mm.

5. The keyboard of claim 1 further comprising a numerical keypad.

6. The keyboard of claim 5 wherein keys at edges of the numerical keypad are raised relative to keys at a center of the numerical keypad.

7. The keyboard of claim 1 further comprising a display.

8. The keyboard of claim 1 wherein letter and number keys exhibit a concave top surface.

9. The keyboard of claim 1 wherein a key selected from an enter key, a space bar, and a shift key exhibit a convex top surface.

10. The keyboard of claim 1 exhibiting a zero degree tilt along a depth axis.

11. The keyboard of claim 1 exhibiting a positive or negative tilt along a depth axis.

12. The keyboard of claim 1 wherein the wave-like vertical profile further comprises a varying key height along a depth axis.

13. The keyboard of claim 1 having keys arranged in a QWERTY configuration.

14. A method of designing a keyboard comprising:
generating a wave-like curve along a width axis; and
fabricating a plurality of keycaps having top surfaces conforming to the wave-like curve.

15. The method of claim 14 wherein the wave-like curve is generated from an equation.

16. The method of claim 14 wherein the wave-like curve is generated by fitting a series of predetermined points corresponding to expected top surfaces of a plurality of keycaps.

17. The method of claim 16 wherein the fitting is performed by a computer aided design (CAD) software program.

18. A method of easing physical strain associated with typing, the method comprising providing a keyboard having keycaps exhibiting a wave-like vertical profile along a width axis.

19. The method of claim 18 wherein the keyboard is provided having a highest key point differing from a lowest key point by between about 3-5 mm.

20. The method of claim 18 wherein the wave-like vertical profile comprises a pair of key troughs separated by a raised key portion, the key troughs positioned at an expected location of hand rest along a home key row.

21. A QWERTY keypad comprising keys whose top surfaces exhibit a continuous wave-like vertical profile conforming to a continuous smooth wave form along a width axis, a first set of keys at edges of the keypad elevated relative to a second set of keys located in troughs at “D” and “K” keys of the home key row, the second set of keys separated by a third, elevated middle set of keys, wherein a difference between a highest key and a lowest key is not greater than 5 mm and a vertical profile of the keys increases along a depth axis from a first row including a space bar keycap to a second row including a number keycap.

22. A method of designing a keyboard comprising:
utilizing a computer to generate a continuous smooth waveform along a horizontal axis; and
fabricating a QWERTY keypad having keys whose top surfaces conform to the computer-generated waveform, a first set of keys at edges of the keypad elevated relative to a second set of keys located in troughs at “D” and “K” keys of a home key row, the second set of keys separated by a third, elevated middle set of keys, wherein a difference between a highest key and a lowest key is not greater than 5 mm and a vertical profile of the keys increases along a depth axis from a bottom row including a space bar keycap to a top row including a number keycap.
